(19) United States
(12) Patent Application Publication
(10) Pub. No.: US 2006/0002091 A1
(43) Pub. Date: Jan. 5, 2006

(54) Micro heat spreader

(76) Inventors: Chung-Zen Lin, Tao Yuan Hsien (TW); Chi-Te Chin, Tao Yuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/983,596

(22) Filed: Nov. 9, 2004

(30) Foreign Application Priority Data
Jul. 2, 2004 (TW) 93210455

(51) Int. Cl. H05K 7/20

(52) U.S. Cl. 361/717

(57) ABSTRACT

A micro heat spreader having an inside vacuum chamber, a bottom recess in the bottom wall thereof, a filling hole formed in the bottom recess in fluid communication with the inside vacuum chamber, a fluid filled into the inside vacuum chamber, and a bronze stopper fastened to the bottom recess to seal the filling hole and maintained in flush with the bottom wall.

### BACKGROUND OF THE INVENTION

1. Field of the Invention

The present invention relates to a micro heat spreader for use with a semiconductor chip to spread heat.

2. Description of the Related Art:

Following fast development of nanotechnology, the number of transistors in an IC chip has been increased in the manner of geometric progression. A high-density IC chip provides a strong operating power. However, a high-density IC chip releases much heat during operation. Various heat dissipation devices have been disclosed to dissipate heat from a semiconductor chip. A micro heat spreader or the so-called flat thermal tube is one of the most efficient heat dissipation devices for this purpose. Conventional micro heat spreaders commonly comprise a flat panel, which defines therein a vacuum chamber, and a fluid filled in the vacuum chamber for spreading heat energy. A regular micro heat spreader further comprises a filling hole in one side wall in fluid communication with the vacuum chamber. During fabrication, a copper tube is inserted into the filling hole for drawing air out of the vacuum chamber. After filling of the fluid into the vacuum chamber, the copper tube is properly cut and sealed by arc welding. After arc welding, the welded outer end of the copper tube protrudes over the outside wall of the micro heat spreader at a distance about 5 mm. The protruded outer end of the copper tube hinders the installation of the micro heat spreader in an electronic package.

There is known another design of micro heat spreader, which has the filling hole formed in the bottom wall. After arc welding to seal the outer end of the copper tube that is inserted into the filling hole for drawing air out of the vacuum chamber, the protruded outer end of the copper tube hinders close attachment of the micro heat spreader to a semiconductor chip, thereby lowering the heat spreading efficiency of the micro heat spreader.

### SUMMARY OF THE INVENTION

The present invention has been accomplished under the circumstances in view. It is one object of the present invention to provide a micro heat spreader, which has a flat bottom wall that can be closely attached to a semiconductor chip close. It is another object of the present invention to provide a micro heat spreader, which effectively spreads heat during operation of the semiconductor chip to which the micro heat spreader is attached. To achieve these and other objects of the present invention, the micro heat spreader comprises an inside vacuum chamber, a bottom recess in the bottom wall thereof, a filling hole formed in the bottom recess in fluid communication with the inside vacuum chamber, a fluid filled into the inside vacuum chamber, and a bronze stopper fastened to the bottom recess to seal the filling hole and maintained in flush with the bottom wall. Alternatively, a metal tube may be used and mounted in the filling hole to substitute for the bronze stopper. After filling of the fluid into the vacuum chamber, the outer end of the metal tube is properly cut and hammered down to close the passage of the filling hole, keeping the closed outer end of the metal tube inside the bottom recess of the micro heat spreader without hindering the installation of the micro heat spreader in a semiconductor chip.

### BRIEF DESCRIPTION OF THE DRAWINGS

FIG. 1(a) is an oblique bottom elevation of a micro heat spreader according to the first embodiment of the present invention.

FIG. 1(b) is a side view in section of the micro heat spreader according to the first embodiment of the present invention.

FIG. 2(a) is an oblique bottom elevation of a micro heat spreader according to the second embodiment of the present invention.

FIG. 2(b) is a side view in section of the micro heat spreader according to the second embodiment of the present invention.

### DETAILED DESCRIPTION OF THE PREFERRED EMBODIMENT

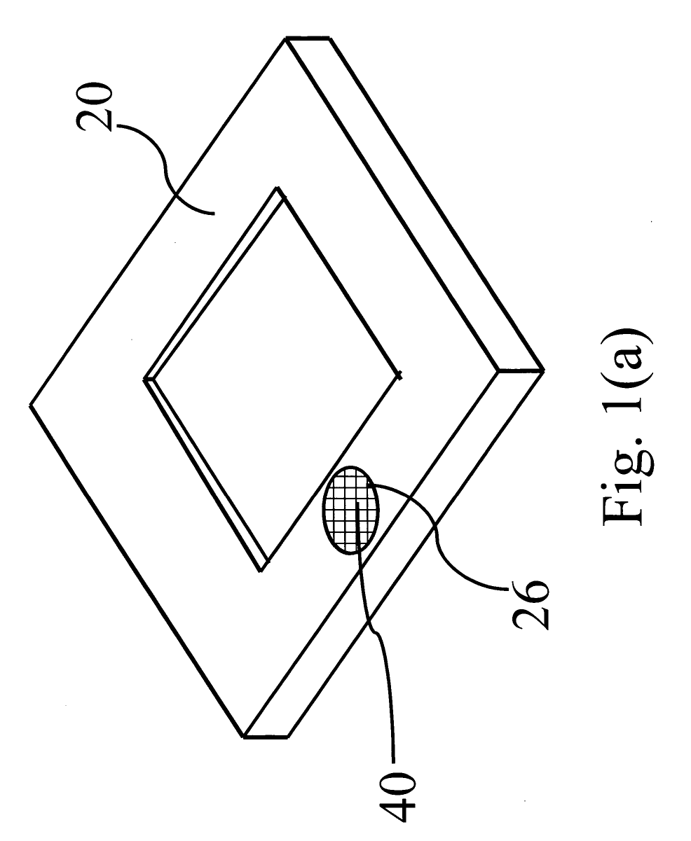

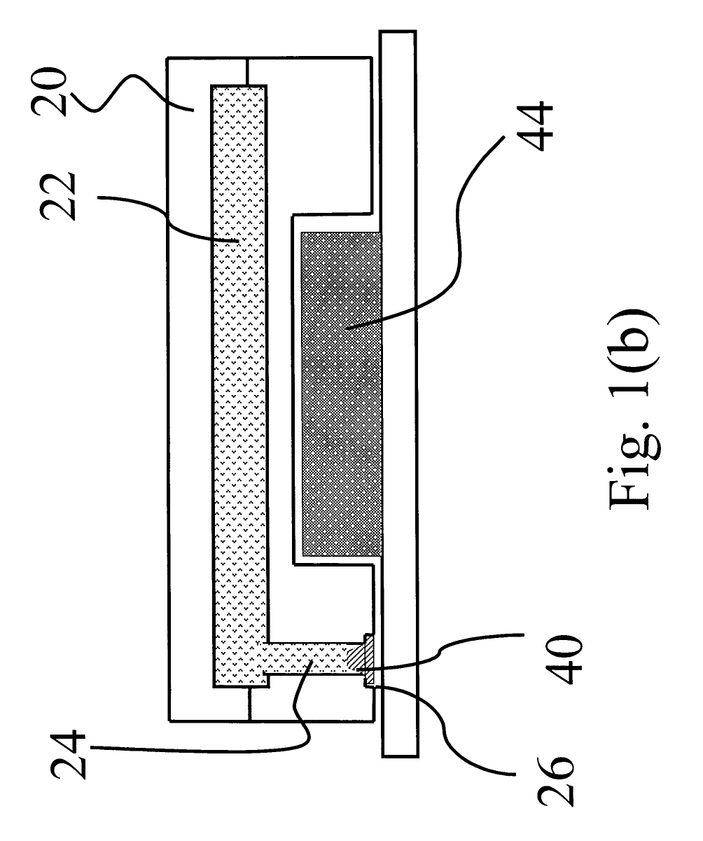

Referring to FIGS. 1(a) and 1(b), a micro heat spreader 20 in accordance with the first embodiment of the present invention is shown comprising an inside vacuum chamber 22, a circular recess 26 formed in the bottom wall, a filling hole 24 formed in the circular recess 26 in fluid communication with the inside vacuum chamber 22, and a stopper 40 fitted into the circular recess 26 to seal the filling hole 24.

During fabrication of the micro heat spreader 20, vacuum pump means (not shown) is attached to the circular recess 25 and the filling hole 24 to draw air out of the inside vacuum chamber 22. After the inside vacuum chamber 22 has been changed into a vacuum status, a fluid or water is filled through the filling hole 24 into the inside vacuum chamber 22, and then the stopper 40 is fastened to the circular recess 26 to seal the filling hole 24. According to this first embodiment, the stopper 40 is a bronze member spot-welded to the circular recess 25 of the micro heat spreader 20 and maintained in flush with the bottom wall of the micro heat spreader 20. FIG. 1(b) shows the micro heat spreader 20 attached to a semiconductor chip 44. Because the stopper 40 is kept in flush with the bottom wall of the micro heat spreader 20, the micro heat spreader 20 can be maintained closely attached to the semiconductor chip 44. Further, the micro heat spreader 20 is fixedly secured to the semiconductor chip 44 by an adhesive by means of the application of an adhesive machine.

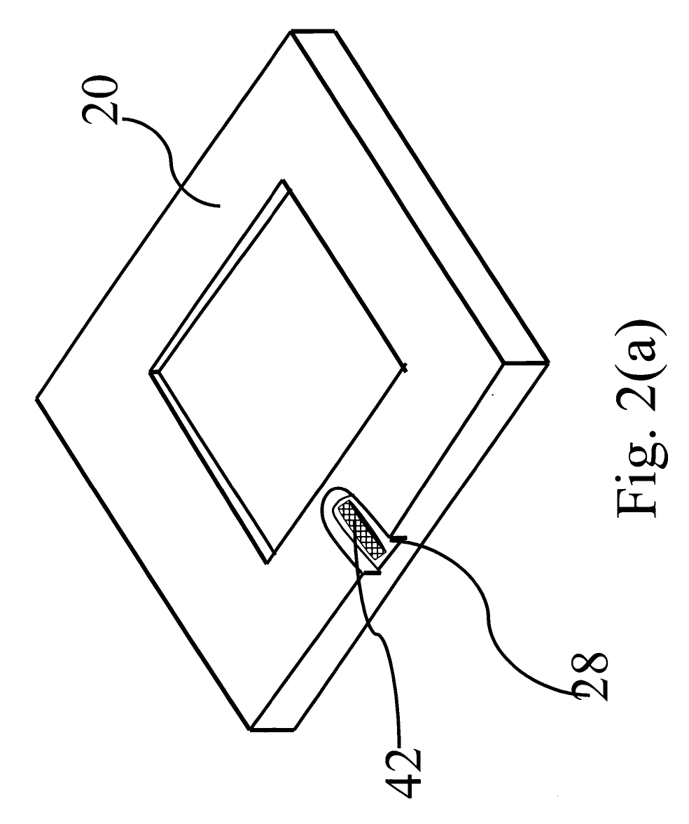

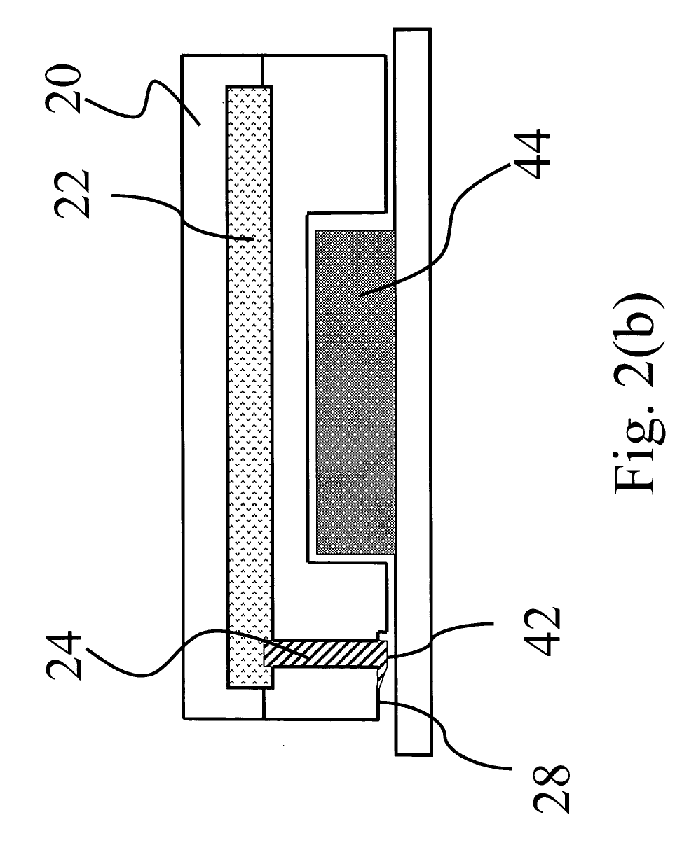

FIGS. 2(a) and 2(b) show a micro heat spreader constructed according to a second embodiment of the present invention. According to this embodiment, the micro heat spreader 20 comprises an inside vacuum chamber 22, a bottom recess 28 formed in the bottom wall, a filling hole 24 formed in the bottom recess 28 in fluid communication with the inside vacuum chamber 22, and a copper tube 42 inserted into the filling hole 24. The bottom recess 28 has a substantially U-shaped profile. The protruding outer end of the copper tube 42 is properly cut and hammered down to close the passage of the filling hole 24 after the inside vacuum chamber 22 has been processed into a vacuum status and filled with a fluid. After fabrication, the closed outer end of the copper tube 42 is kept inside the bottom recess 28 and spaced from the bottom wall of the micro heat spreader 20 at a distance. Therefore, the closed outer end of the copper tube 42 does not hinder the installation of the micro heat spreader 20 in a semiconductor chip 44.

A prototype of micro heat spreader has been constructed with the features of FIGS. 1 and 2. The micro heat spreader functions smoothly to provide all of the features discussed earlier.

Although particular embodiment of the invention have been described in detail for purposes of illustration, various modifications and enhancements may be made without departing from the spirit and scope of the invention.

What the invention claimed is:

1. A micro heat spreader comprising an inside vacuum chamber, a recess in an outside wall thereof, and a filling hole formed in said recess in fluid communication with said inside vacuum chamber.

2. The micro heat spreader as claimed in claim 1, further comprising a fluid filled in said inside vacuum chamber.

3. The micro heat spreader as claimed in claim 1, wherein said recess has a circular shape.

4. The micro heat spreader as claimed in claim 1, wherein said recess has a U-shaped profile.

5. The micro heat spreader as claimed in claim 1, further comprising a filling tube mounted in said filling hole, said filling hole having an inner end extended to said inside vacuum chamber and an outer end extended to said recess.

6. The micro heat spreader as claimed in claim 5, wherein said filling tube is a metal tube.

7. The micro heat spreader as claimed in claim 6, wherein said metal tube is made of a copper alloy.

8. The micro heat spreader as claimed in claim 1, further comprising a stopper fastened to said recess to seal said filling hole.

9. The micro heat spreader as claimed in claim 8, wherein said stopper is made of a metal material.

10. The micro heat spreader as claimed in claim 9, wherein said metal material is selected from one of the material group including nickel, bronze, and their alloys.

11. The micro heat spreader as claimed in claim 1, wherein said outside wall is at a bottom side of the micro heat spreader to be attached to a semiconductor chip.
